(19) United States
(12) Patent Application Publication
(10) Pub. No.: US 2026/0167789 A1
(43) Pub. Date: Jun. 18, 2026

(54) ACTIVE ENERGY RAY-CURABLE COMPOSITION, MULTILAYER BODY, AND METHOD FOR PRODUCING MULTILAYER BODY

(71) Applicant: NIPPON STEEL Chemical & Material Co., Ltd., Tokyo (JP)

(72) Inventors: Toshihiro KAWATANI, Tokyo (JP); Takashi SAITO, Tokyo (JP)

(73) Assignee: NIPPON STEEL Chemical & Material Co., Ltd., Tokyo (JP)

(21) Appl. No.: 19/127,462

(22) PCT Filed: Dec. 13, 2023
(86) PCT No.: PCT/JP2023/044715

§ 371 Date: May 6, 2025

(30) Foreign Application Priority Data
Dec. 28, 2022 (JP) 2022-211267

(51) Int. Cl. C08J 7/04; B05D 1/00; B05D 3/06; B05D 7/00; C08F 2/50; C08F 290/06; C08K 3/36; C09D 155/00; C23C 14/10; C23C 14/22

(52) U.S. Cl. CPC C08J 7/0423; B05D 1/005; B05D 3/067; B05D 7/52; C08F 2/50; C08F 290/068; C08K 3/36; C09D 155/005; C23C 14/10; C23C 14/221; B05D 2201/02; C08J 2323/08; C08J 2345/00; C08J 2351/08

(57) ABSTRACT

The present invention relates to a laminate including a cycloolefin resin substrate. Provided is a laminate including a cycloolefin resin substrate on which a cured coating layer of an active energy ray-curable composition and an inorganic substance layer are sequentially laminated, the laminate causing no cracking and no peeling off after a weather resistance test, having excellent steel wool resistance and pencil hardness. The laminate includes a cycloolefin resin substrate (I) on which a cured coating layer (II) of an active energy ray-curable composition, and an inorganic substance layer (III) are sequentially laminated, wherein the cured coating layer (II) contains a reactive silicone resin (A), a polyfunctional (meth)acrylic monomer (B), and a benzophenone photopolymerization initiator (C), with a component (A) content of 30 to 90 parts by weight, a component (B) content of 20 to 80 parts by weight, and a component (C) content of 0.1 to 10 parts by weight, relative to 100 parts by weight in total of the components (A), (B), and (C); the total number of moles of (meth)acrylic of the polyfunctional (meth)acrylic monomer (B) contained in 100 g of the composition is 0.25 to 0.80; and the reactive silicone resin (A) is obtained through hydrolysis and condensation of an alkoxysilane represented by the following general formula (i) and a compound containing an alkyl silicate represented by the following general formula (ii) or a partial hydrolysate thereof:

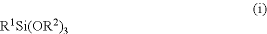

wherein R¹ is an organic functional group having a (meth)acryloyl group, and R² represents a hydrogen atom or an alkyl group having 1 to 5 carbon atoms;

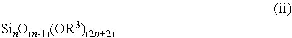

wherein n represents a number of from 1 to 20, and R³ represents a hydrogen atom or an alkyl group having 1 to 5 carbon atoms.

### TECHNICAL FIELD

The present invention relates to a laminate including a cycloolefin-based resin substrate, and relates to a laminate including a cycloolefin resin on which a cured coating layer of an active energy ray-curable composition having excellent adhesion to the substrate, capable of imparting properties such as scratch resistance, and an inorganic substance layer are sequentially laminated, the laminate having excellent weather resistance; and a method for producing the same.

In recent years, cycloolefin resins have been increasingly used as optical components for mobile phones, smartphones, liquid crystal displays, etc., due to having functionality such as high transparency and low hygroscopicity. Cycloolefin resins are easily scratched due to having relatively low surface hardness. Accordingly, a hard coat layer is provided on the surface thereof. However, the adhesion between the cycloolefin resin and the hard coat layer has not been necessarily sufficient. Therefore, prior to forming the hard coat layer, the surface of the cyclic olefin-based resin needs to be subjected to a step for easy-adhesion processing such as corona discharging, plasma processing, ozone processing and application of an easy-adhesion primer composition (Patent Literature 1).

Furthermore, in Patent Literature 2, a laminate of a cycloolefin resin layer and a layer containing a cycloolefin resin layer, a diphenyl sulfide compound, a benzophenone compound and a compound having a (meth)acryloyl group is proposed, and in Patent Literature 3, a composition containing a polyfunctional (meth)acrylate, a benzophenone compound and a polysiloxane is proposed. However, in some cases, the hardness of the laminate and the adhesion to the cycloolefin resin are not sufficient.

On the other hand, an inorganic substance layer has been conventionally formed on a plastic substrate to provide a mechanical, electrical, optical, or chemical function. In this case, in order to ensure sufficient interlayer adhesion between the plastic substrate and the inorganic substance layer, a laminate structure with a cured resin layer of curable resin composition interposed therebetween has been proposed. For example, in Patent Literature 4, a surface-modified plastic plate for windows including a cured film of an active energy ray-curable primer composition formed on a plastic plate, with an inorganic substance layer formed thereon, is described. However, in the case where the substrate is made of cycloolefin resin, the interlayer adhesion between the substrate and the cured resin layer, and/or the interlayer adhesion between the cured resin layer and the inorganic substance layer may be insufficient. Furthermore, a laminate sequentially including a cycloolefin resin, a cured coating film, and an inorganic substance layer has problems that cracks occur in the inorganic substance layer due to deterioration of the cured coating film in a xenon weather resistance test, or the inorganic substance layer is easily peeled off from the cured coating film, resulting in poor steel wool resistance.

### CITATION LIST

### Patent Literature

Patent Literature 1: Japanese Translation of PCT International Application Publication No. 2008-518280
Patent Literature 2: JP2015-127102 A
Patent Literature 3: JP2016-105164 A
Patent Literature 4: JP4-202240 A

### SUMMARY OF INVENTION

### Technical Problem

The present invention relates to a laminate including a cycloolefin resin substrate, and more specifically relates to a laminate including a cycloolefin resin on which a cured coating layer of an active energy ray-curable composition having excellent adhesion to the substrate, capable of imparting properties such as scratch resistance, and an inorganic substance layer, are sequentially laminated, the laminate hardly causing cracking or peeling off after a xenon weather resistance test, having excellent steel wool resistance and pencil hardness; and a method for producing the same. The present invention also relates to the active energy ray-curable composition.

### Solution to Problem

The present inventors have found that such a laminate including particularly a cured coating layer (II) between a cycloolefin resin substrate (I) and an inorganic substance layer (III), formed of an active energy ray-curable composition containing a polymerizable compound having a specific structure at a specific proportion can solve the problem, and have arrived at the present invention.

In other words, the present invention relates to a laminate comprising a cycloolefin resin substrate (I) on which a cured coating layer (II) of an active energy ray-curable composition, and an inorganic substance layer (III) are sequentially laminated, wherein
the cured coating layer (II) contains a reactive silicone resin (A), a polyfunctional (meth)acrylic monomer (B), and a benzophenone photopolymerization initiator (C), with a component (A) content of 30 to 90 parts by weight, a component (B) content of 20 to 80 parts by weight, and a component (C) content of 0.1 to 10 parts by weight, relative to 100 parts by weight in total of the components (A), (B), and (C);
the total number of moles of (meth)acrylic of the polyfunctional (meth)acrylic monomer (B) contained in 100 g of the composition is 0.25 to 0.80; and
the reactive silicone resin (A) is obtained through hydrolysis and condensation of an alkoxysilane represented by the following general formula (i) and a compound containing an alkyl silicate represented by the following general formula (ii) or a partial hydrolysate thereof:

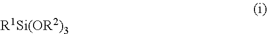

wherein R¹ is an organic functional group having a (meth)acryloyl group, and R² represents a hydrogen atom or an alkyl group having 1 to 5 carbon atoms;

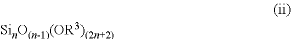

wherein n represents a number of from 1 to 20, and R³ represents a hydrogen atom or an alkyl group having 1 to 5 carbon atoms.

In the present invention, in a weather resistance test including exposing the surface of the inorganic substance layer (III) of the laminate to the light from a xenon lamp at an illuminance of 2.4 W/m² (420 nm) for 150 hours under conditions at a temperature of 55° C. and a relative humidity of 30% Rh, the laminate causes no cracking or no peeling off after the weather resistance test, and no scratches are visually observed after the inorganic substance layer (III) surface is reciprocated 10 times with #0000 steel wool under a load of 250 g/cm³.

Furthermore, in the laminate of the present invention, the film thickness of the cured coating layer (II) is preferably in the range of 0.5 to 20 μm.

In the laminate of the present invention, preferably, the cycloolefin resin substrate (I) is not subjected to easy-adhesion processing.

The present invention also relates to an active energy ray-curable composition for forming the cured coating layer (II) of the laminate, comprising:
a reactive silicone resin (A), a polyfunctional (meth)acrylic monomer (B), and a benzophenone-based photopolymerization initiator (C), with a component (A) content of 30 to 90 parts by weight, a component (B) content of 20 to 80 parts by weight, and component (C) content of 0.1 to 10 parts by weight, relative to 100 parts by weight in total of the components (A), (B), and (C);
wherein the total number of moles of (meth)acrylic of the polyfunctional (meth)acrylic monomer (B) contained in 100 g of the composition is of 0.25 to 0.80;
the reactive silicone resin (A) is obtained through hydrolysis and condensation of an alkoxysilane represented by the general formula (i) and a compound containing an alkyl silicate represented by the general formula (ii) or a partial hydrolysate thereof, and in the blending ratio between the component (i) represented by the formula (i) and the compound containing the component (ii) as alkyl silicate represented by the formula (ii) or a partial hydrolysate thereof, [Moles of Si derived from compound containing component (ii)/Moles of Si derived from component (i)] satisfies the range of 0.5 to 4.0 relative to 100 moles of Si in total contained in both.

In the active energy ray-curable composition for forming the cured coating layer (II) of the laminate of the present invention, the polyfunctional (meth)acrylic monomer (B) preferably includes, as main component, a polyorganosilsesquioxane represented by the following general formula (iii) and having a cage-type structure in the structural unit,

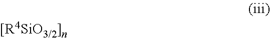

wherein R⁴ is an organic functional group having a (meth)acryloyl group, and n is 8, 10 or 12.

The present invention also relates to a method for producing the laminate, comprising the steps of: applying an active energy ray-curable composition onto a cycloolefin-based resin substrate (I) to form a coating layer of the active energy ray-curable composition; exposing the coating layer of the active energy ray-curable composition to active energy rays to form a cured coating layer (II) of the active energy ray-curable composition; and forming at least one inorganic substance layer (III) on the cured coating layer (II) by dry film deposition.

### Advantageous Effects of Invention

The present invention relates to a laminate including a cycloolefin-based resin substrate. The present invention is capable of providing a laminate including a cycloolefin resin substrate on which a cured coating layer of an active energy ray-curable composition having excellent adhesion to the substrate, capable of imparting properties such as scratch resistance, and an inorganic substance layer, are sequentially laminated, the laminate hardly causing cracking or peeling off after a xenon weather resistance test, having excellent steel wool resistance; and a method for producing the same. The present invention is also capable of providing an active energy ray-curable composition suitable for forming the cured coating layer.

### DESCRIPTION OF EMBODIMENTS

Hereinafter, each element constituting the present invention will be described in detail. Since the following description is an example embodiment of the present invention, the present invention is not limited to the following description as long as it does not exceed the gist thereof. In addition, in the case of using an expression “to” in the present specification, the expression includes prescribed and postscribed numerical values or physical property values. In the present invention, in the case of using an expression “(meth)acrylic”, the expressing means one or both of “acrylic” and “methacrylic”. The same applies to “(meth)acrylate” and “(meth)acryloyl”.

The laminate of the present invention is a laminate including a cured coating layer (II) of an active energy ray-curable composition formed on at least one surface of a cycloolefin resin substrate (I), and an inorganic substance layer (III) sequentially laminated thereon.

Preferably, the cycloolefin resin substrate (I) is not subjected to easy-adhesion processing from the point of view of shortening the production process of the laminate. Examples of the easy-adhesion processing include a known easy-adhesion processing such as corona discharging, plasma processing, ozone processing, and application of an easy-adhesion primer composition.

As the cycloolefin resin (I), any homopolymer or copolymer may be used without any particular limitation, so long as a cyclic olefin is polymerized. Examples of commercially available cyclic olefin resins include “ZEONOR” manufactured by Zeon Corporation, “ARTON” manufactured by JSR Corporation, “TOPAS” manufactured by Polyplastics Co., Ltd., and “APL” manufactured by Mitsui Chemicals, Inc. The shape of the cycloolefin substrate (I) may be a film or a molded body, and the thickness thereof is not particularly limited.

The inorganic substance layer (III) in the present invention is not particularly limited as long as it is formed by dry film deposition, and may be selected according to the properties to be imparted to the laminate. Examples thereof include a layer mainly composed of at least one of various metals, metal oxides, nitrides, and sulfides having elements such as Si, Ti, Zn, Al, Ga, In, Ce, Bi, Sb, B, Zr, Sn, and Ta.

The inorganic substance layer (III) in the present invention may be at least one layer or more, and may include a plurality of layers. In the case where the inorganic substance layer (III) include a plurality of layers, the laminating sequence of the layers and the type of the inorganic substance layer (III) are not particularly limited. Examples of the inorganic substance layer (III) may include various functional layers such as an anti-reflection layer, an ultraviolet absorbing layer, and a functional layer.

Among these, it is preferable that the inorganic substance layer (III) be a layer made of metal oxide, and in particular, made of silicon oxide compound, from the viewpoints of high hardness, low reflectance, interlayer adhesion with the cured coating layer (II), and transparency of the laminate. Examples of the silicon oxide compounds include silicon monoxide, silicon dioxide, and silicon suboxide.

The method for laminating the inorganic substance layer (III) in the present invention is not particularly limited as long as the method is dry film deposition, and examples of the dry film deposition include physical vapor deposition (hereinafter also referred to as “PVD”) such as resistance heating deposition, electron beam deposition, molecular beam epitaxy, ion beam deposition, ion plating, ion-assisted deposition, and sputtering, and chemical vapor deposition (hereinafter also referred to as “CVD”) such as thermal CVD, plasma CVD, photo CVD, epitaxial CVD, atomic layer CVD, and Cat-CVD. Ion-assisted deposition, by which a stable film having high adhesion and high density can be obtained, is preferred. The dry film deposition referred to here is a method of processing the surface of a material using a gas phase or a molten state, and may be generally referred to as dry process.

The thickness of the inorganic substance layer (III) is preferably 10 nm or more from the viewpoint of scratch resistance, and more preferably 20 nm or more to maintain sufficient abrasion resistance. The upper limit of the thickness per one inorganic substance layer (III) is not particularly limited, preferably 5 μm or less, and particularly preferably 2 μm or less. With a thickness of the inorganic substance layer (III) of less than 10 nm, sufficient scratch resistance may not be achieved.

As described above, the cured coating layer (II) of the present invention includes an active energy ray-curable composition containing components (A) to (C) described below, and is a cured product formed from the composition. The reactive silicone resin (A) in the active energy ray-curable composition for forming the cured coating layer (II) of the present invention is blended preferably in an amount of 30 to 90 parts by weight relative to 100 parts by weight in total of the components (A), (B) and (C). The amount is preferably in the range of 32 to 80 parts by weight, more preferably 35 to 70 parts by weight. With a too small amount, the cured coating layer (II) may deteriorate in a weather resistance test after making of the laminate, so that the adhesion to the inorganic substance layer (III) and the steel wool resistance may deteriorate. With a too large amount, the adhesion between the cycloolefin resin substrate (I) and the cured coating layer (II) may be lowered.

The reactive silicone resin (A) in the active energy ray-curable composition for forming the cured coating layer (II) of the present invention is obtained through hydrolysis and condensation of the component (i) (alkoxysilane) represented by the formula (i) and a compound containing an alkyl silicate represented by the formula (ii) or a compound containing the component (ii) as a partial hydrolysate thereof. Here, in the blending ratio between the component (i) and the compound containing the component (ii), the molar ratio represented by [Moles of Si derived from compound containing component (ii)/Moles of Si derived from component (i)] is desired to be in the range of 0.5 to 4.0, relative to 100 moles of Si in total contained in both. The range is preferably 0.7 to 3.7, more preferably 0.9 to 3.2. With a too small amount, the cured coating layer (II) may deteriorate in a weather resistance test after making of the laminate, so that the adhesion to the inorganic substance layer (III) and the steel wool resistance may deteriorate. With a too large amount, cracking or peeling off may be caused.

Examples of the alkoxysilane represented by the general formula (i) include 3-(meth)acryloxypropyl trimethoxysilane, 2-(meth)acryloxyethyl trimethoxysilane, (meth)acryloxymethyl trimethoxysilane, (meth)acryloxymethyl triethoxysilane, and 3-(meth)acryloxypropyl triethoxysilane.

Examples of the alkyl silicate represented by the general formula (ii) include linear and branched alkyl silicates such as methyl silicate, ethyl silicate, isopropyl silicate, n-propyl silicate, isobutyl silicate, n-butyl silicate, n-pentyl silicate and acetyl silicate. In addition to the alkyl silicate represented by the formula (ii) or the component (ii) as partial hydrolysate thereof, a cyclic alkyl silicate represented by the following general formula (iv) or a partial hydrolysate thereof [component (iv)] may be included:

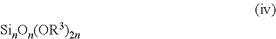

wherein n represents a number of from 1 to 20, and R³ represents a hydrogen atom or an alkyl group having 1 to 5 carbon atoms.

In other words, the “compound including an alkyl silicate represented by the formula (ii) or a component (ii) as partial hydrolysate thereof” may contain a cyclic alkyl silicate represented by the formula (iv) or a component (iv) as partial hydrolysate thereof. In that case, in the molar ratio of Si, the Si content of the component (iv) is added to “moles of Si derived from a compound containing component (ii)”. More preferably, methyl silicate, ethyl silicate or a partial hydrolysate thereof is preferred from the viewpoint of rapid reactions of hydrolysis and condensation.

As a method for obtaining the reactive silicone resin (A) through hydrolyzation and condensation of a mixture containing compounds containing the components (i) and (ii), co-hydrolyzation of the mixture containing compounds containing the components (i) and (ii) in acidic water having a pH of 1 to 7, preferably 2 to 5, may be performed. For the pH adjustment, organic or inorganic acids such as hydrogen fluoride, hydrochloric acid, nitric acid, formic acid, acetic acid, propionic acid, oxalic acid, citric acid, maleic acid, benzoic acid, malonic acid, glutaric acid, glycolic acid, methanesulfonic acid, and toluenesulfonic acid may be used. Further, a solid acid catalyst such as a cation exchange resin having carboxylic acid groups or sulfonic acid groups on the surface may be used as catalyst. The amount of the acid or acid catalyst used is preferably 0.0001 to 20 wt % relative to the product.

The presence of water is required for the hydrolysis reaction. The amount of water may be at least an amount sufficient to hydrolyze the hydrolyzable groups in the silicon compound in the mixture, and is preferably equivalent to 0.5 to 2.0 times the theoretical amount (moles) of the number of hydrolyzable groups. In the case where the mixture contains the other silane compounds, the hydrolyzable groups thereof are included in the count. In the case where an aqueous solution of acid catalyst is added, the water is included in the count. With an insufficient amount of water, hydrolysis proceeds insufficiently, while with too much water, the coatability and drying efficiency is lowered due to remaining water.

A dehydration condensation reaction of the silanol groups produced in parallel with the hydrolysis occurs to form a reactive silicone resin (A). The condensation is performed at room temperature or at temperature heated to 120° C. or less, and more preferably at 30° C. or more and 100° C. or less. In the case where the temperature is low, the hydrolysis and condensation reactions take a long time, so that productivity decreases. In the case where the temperature is too high beyond the range, insolubilization may occur.

The weight average molecular weight (hereinafter also referred to as “Mw”) of the reactive silicone resin (A) is not particularly limited, preferably in the range of 200 to 10000. Mw is more preferably 500 to 8000, still more preferably 600 to 7000, and particularly preferably 700 to 6000. The resulting structure includes linear, branched, and cyclic forms, constituting a mixture with a molecular weight distribution. With an Mw of less than 200, the hydrolysis and condensation reactions proceed insufficiently, while with an Mw of more than 10000, insolubilization or poor storage stability may be caused. Thus, the reactive silicone resin (A) in the present invention is obtained as a mixture having ranges in structures and properties by the reaction. Accordingly, there exist some circumstances in which it is impossible or utterly impractical to define the reactive silicone resin (A) directly based on the structure or characteristics alone (so-called impossible or impractical circumstances).

In the present disclosure, Mw means a value obtained by measuring the molecular weight by GPC (gel permeation chromatography) in terms of polystyrene as standard substance.

The polyfunctional (meth)acrylic monomer (B) for forming the cured coating layer (II) of the present invention is desired to be blended in an amount of 20 to 80 parts by weight relative to 100 parts by weight in total of components (A), (B) and (C). The range is preferably 25 to 75 parts by weight, and more preferably 30 to 70 parts by weight.

The total number of moles of the (meth)acrylic of the polyfunctional (meth)acrylic monomer (B) contained in 100 g of the active energy ray-curable composition that forms the cured coating layer (II) is controlled to 0.25 to 0.8. The range is preferably 0.27 to 0.75, and more preferably 0.29 to 0.7. With a too small number of moles of (meth)acrylic, the adhesion to the cycloolefin resin substrate (I) may be lowered. With a too large number, peeling off may occur between the cured coating layer (II) and the inorganic substance layer (III) after a weather resistance test.

Examples of the polyfunctional (meth)acrylic monomer (B) include pentaerythritol triacrylate, glycerin dimethacrylate, dipentaerythritol pentaacrylate, dipentaerythritol tetraacrylate, 2-hydroxy-3-acryloyloxypropyl methacrylate, trimethylolpropane triacrylate, pentaerythritol tetraacrylate, dipentaerythritol hexaacrylate, dimethylol tricyclodecane diacrylate, 1,6-hexanediol diacrylate, and 1,9-nonanediol diacrylate. In addition to these, compounds in which all the hydroxy groups of pentaerythritol and dipentaerythritol are modified with glycols of ethylene and isopropylene, or γ-butyrolactone to produce a skeleton, of which all the terminal hydroxy groups are modified with unsaturated groups, may be also used. Alternatively, examples include urethane acrylates and acrylic copolymer acrylates. These compounds may be used alone or as a mixture of two or more.

As the polyfunctional (meth)acrylic monomer (B), a polyorganosilsesquioxane compound may be used that includes, as main component, a polyorganosilsesquioxane represented by the following general formula (iii) and having a cage-type structure in the structural unit,

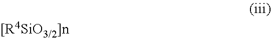

wherein R⁴ is an organic functional group having a (meth)acryloyl group, and n is 8, 10 or 12. Through use of the compound of general formula (iii), the steel wool resistance and pencil hardness required for the cured coating layer (II) can be improved. With the increase in the amount of the compound blended, the crosslink density increases to make the layer hard and brittle, which may cause cracking or peeling off. Therefore, the amount used in the whole component (B) is preferably 25 wt % or less, more preferably 23 wt % or less.

The polyfunctional (meth)acrylic monomer (B) represented by the general formula (iii) has an organic functional group having a (meth)acryloyl group on a silicon atom in the molecule. Examples of the specific structure of the cage-type polyorganosilsesquioxane in which n in the general formula (iii) is 8, 10 or 12 include cage-type structures shown in the following structural formulas (1), (2), and (3), respectively. R in the following formulas represents the same as R⁴ in the general formula (iii).

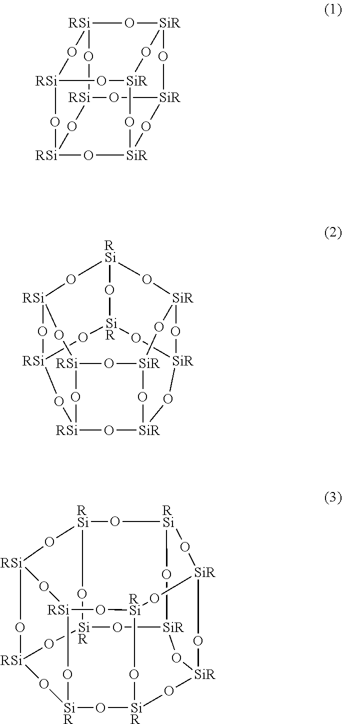

Here, the polyfunctional (meth)acrylic monomer (B) represented by the general formula (iii) may be produced by the method described in JP2004-143449 A and the like.

For example, the production method may include the steps of hydrolyzing and partially condensing a silicon compound represented by the general formula “RSiX₃” in the presence of a polar solvent and a basic catalyst, and further recondensing the resulting hydrolysis product in the presence of a non-polar solvent and a basic catalyst.

Here, in the general formula “RSiX₃”, R is an organic functional group having a (meth)acryloyl group. Specific examples of preferable R include a 3-methacryloxypropyl group, a methacryloxymethyl group and a 3-acryloxypropyl group. X represents a hydrolyzable group.

In the silicon compound represented by the general formula “RSiX₃” for use as a raw material, the hydrolyzable group X is not particularly limited as long as it is a hydrolyzable group. Examples thereof include an alkoxyl group and an acetoxy group, and an alkoxyl group is preferred. Examples of the alkoxyl group include a methoxy group, an ethoxy group, an n- or i-propoxy group, an n-, i- or t-butoxy group. A methoxy group is preferred due to having high reactivity.

Preferred examples of the compound among the silicon compounds represented by RSiX₃ include methacryloxymethyltriethoxysilane, methacryloxymethyltrimethoxysilane, 3-methacryloxypropyltrichlorosilane, 3-methacryloxypropyltrimethoxysilane, 3-methacryloxypropyltriethoxysilane, 3-acryloxypropyltrimethoxysilane, and 3-acryloxypropyltrichlorosilane. Among them, it is preferable to use 3-methacryloxypropyltrimethoxysilane, due to easy availability of raw materials.

Examples of the basic catalyst for use in the hydrolysis reaction include alkali metal hydroxides such as potassium hydroxide, sodium hydroxide and cesium hydroxide, and ammonium hydroxide salts such as tetramethylammonium hydroxide, tetraethylammonium hydroxide, tetrabutylammonium hydroxide, benzyltrimethylammonium hydroxide and benzyltriethylammonium hydroxide. Among these, tetramethylammonium hydroxide is preferably used due to having high catalytic activity. The basic catalysts are usually used as aqueous solutions.

Regarding the hydrolysis reaction conditions, the reaction temperature is preferably 0 to 60° C., more preferably 20 to 40° C. At a reaction temperature of lower than 0° C., the reaction rate is slow and the hydrolyzable groups remain in an unreacted state, resulting in a long reaction time. On the other hand, at a temperature higher than 60° C., due to the too fast reaction rate, a complicated condensation reaction proceeds, so that the hydrolysis product tends to have a high molecular weight. Further, the reaction time is preferably 2 hours or more. With a reaction time of less than 2 hours, the hydrolysis reaction may not proceed sufficiently and the hydrolyzable groups may remain in an unreacted state.

The presence of water is essential for the hydrolysis reaction, and water may be supplied from an aqueous solution of the basic catalyst, or may be added separately. The amount of water may be at least to hydrolyze the hydrolyzable groups, preferably 1.0 to 1.5 times the theoretical amount. In addition, it is necessary to use an organic polar solvent for hydrolysis, and alcohols such as methanol, ethanol, and 2-propanol, or other organic polar solvents may be used as the organic polar solvent. Lower alcohols having 1 to 6 carbon atoms that are soluble in water are preferred, and use of 2-propanol is more preferred. Use of a non-polar solvent is not preferred, because a uniform reaction system cannot be obtained, and the hydrolysis reaction proceeds insufficiently, so that unreacted hydrolyzable groups remain.

After completion of the hydrolysis reaction, the water or water-containing reaction solvent is separated. For separation of water or the water-containing reaction solvent, means such as vacuum evaporation may be employed. In order to sufficiently remove water and other impurities, means including adding a non-polar solvent to dissolve the hydrolysis reaction product, washing the solution with saline or the like, and then drying the solution with a desiccant such as anhydrous magnesium sulfate may be employed. In the case where the non-polar solvent is separated by means such as evaporation, the hydrolysis reaction product may be recovered. However, in the case where the non-polar solvent is usable as non-polar solvent in the subsequent reaction, the separation thereof is not required.

In a hydrolysis reaction, a condensation reaction of hydrolysate occurs along with the hydrolysis. The product in hydrolysis accompanying the condensation reaction of hydrolysate is usually a colorless viscous liquid with a number average molecular weight of 1400 to 5000. The hydrolysis product has a number average molecular weight of 1400 to 3000 depending on the reaction conditions, and a majority or preferably almost all of the hydrolyzable groups X are replaced by OH groups, and further, a majority or preferably 95% or more of the OH groups are condensed. The structure of the hydrolysis products includes a plurality types of silsesquioxanes including cage-types, ladder-types, and random-types. The compounds having a cage-type structure mainly includes incomplete cage-shaped structures with a partly open cage, with a less proportion of a complete cage structure. Accordingly, the hydrolysis product obtained through the hydrolysis is heated in an organic solvent in the presence of a basic catalyst to further condense the siloxane bonds (referred to as re-condensation), so that silsesquioxane having a cage-type structure is selectively produced.

Specifically, the production is performed as follows. That is, after completion of the hydrolysis reaction as described above, water or a water-containing reaction solvent is separated, and then a recondensation reaction is performed in the presence of a non-polar solvent and a basic catalyst. Regarding the reaction conditions for the recondensation reaction, the reaction temperature is preferably in the range of 100 to 200° C., more preferably 110 to 140° C. At a too low reaction temperature, sufficient driving force for causing the recondensation reaction cannot be obtained, so that the reaction does not proceed. At a too high reaction temperature, the (meth)acryloyl group may cause a self-polymerization reaction, so that suppression of the reaction temperature or addition of a polymerization inhibitor or the like is required. The reaction time is preferably 2 to 12 hours. The amount of the non-polar solvent used is preferably an amount sufficient to dissolve the hydrolysis reaction product, and the amount of the basic catalyst used is preferably in the range of 0.1 to 10 parts by mass (wt %) relative to the hydrolysis reaction product.

As the non-polar solvent, one having no or almost no solubility in water may be used, and hydrocarbon solvents are preferred. Such hydrocarbon solvents include non-polar solvents having a low boiling point such as toluene, benzene and xylene. Among them, toluene is preferably used. As the basic catalysts, basic catalysts used in the hydrolysis reaction may be used, and examples thereof include alkali metal hydroxides such as potassium hydroxide, sodium hydroxide, and cesium hydroxide, or ammonium hydroxide salts such as tetramethylammonium hydroxide, tetraethyl ammonium hydroxide, tetrabutylammonium hydroxide, benzyltrimethylammonium hydroxide, and benzyltriethylammonium hydroxide. Catalysts soluble in a non-polar solvent such as tetraalkylammonium are preferred.

The hydrolysis product to be used for recondensation is preferably washed with water, dehydrated and concentrated, though it may be used without washing with water and dehydration. Although water may be present during the reaction, intentional addition is not required and limiting to about a water content brought in from the basic catalyst solution is preferred. In the case where the hydrolysis products are not sufficiently hydrolyzed, water more than the theoretical amount of water required to hydrolyze the remaining hydrolyzable groups is required. However, a sufficient hydrolysis reaction is usually performed. After the recondensation reaction, the catalyst is washed away with water. Through condensation, a silsesquioxane mixture is obtained. In the resulting silsesquioxane mixture, the number of silicon atoms and the number of (meth)acryloyl groups in the molecule are preferably equal to each other.

It is considered that although the constituent components of the silsesquioxane mixture thus obtained are different depending on the reaction conditions and the state of the hydrolysis product, the constituent components include a plurality of types of cage-type silsesquioxanes in an amount of 70% or more of the total, and the remainder including ladder-type randomly cross-linked silsesquioxanes. Since separation of these is difficult and requires a lot of labor, in the case of using the cage-type silsesquioxane represented by the general formula (iii) in the present invention, a silsesquioxane containing 70% or more of a plurality types of cage-type silsesquioxanes is preferably used. Incidentally, with a cage-type silsesquioxane content of 70% or more, the same effects may be obtained. The constituent components of the plurality types of cage-type silsesquioxanes include 20 to 40% of T8 represented by general formula (1), 40 to 50% of T10 represented by general formula (2), and other component T12 represented by general formula (3). T8 can be separated by leaving the silsesquioxane mixture at 20° C. or less so as to be precipitated as needle-like crystals. The content ratio of the cage-type silsesquioxane can be checked by using, for example, GPC or LC-MS.

Such a compound may be a mixture of T8 to T12, or may be one or two of T8 and the like separated or concentrated from the mixture, though not limited to the compound obtained by the production method described above.

The number of moles of (meth)acrylic of the polyfunctional (meth)acrylic monomer (B) contained in 100 g thereof represents the sum of the number of moles of acrylic of the polyfunctional (meth)acrylic monomer (B) per 100 g of the active energy ray-curable composition (Number of acrylic functional groups/Molecular weight g·mol⁻¹).

It is preferable that the benzophenone photopolymerization initiator (C) to form the cured coating layer (II) of the present invention be blended in an amount of 0.1 to 10 parts by weight relative to 100 parts by weight in the total of the components (A), (B) and (C). The range of 0.5 to 8 is preferred, and the range of 1 to 5 is more preferred. With a too small amount, due to insufficient cross-linking, the adhesion is lowered and the elastic modulus is also lowered, so that the desired steel wool resistance and pencil hardness may not be obtained. With a too large amount, the transmittance of the active energy ray-curable composition is lowered, so that the supply of light to the depths of the cured coating layer (II) is hindered during curing. As a result, crosslinking at the interface between the cured coating layer (II) and the cycloolefin resin substrate (I) proceeds insufficiently, so that adhesion may be lowered.

Examples of the benzophenone-based photopolymerization initiators (C) include benzophenone, alkyl-substituted benzophenones such as 4-methylbenzophenone and 4,4′-dimethylbenzophenone; alkenyl-substituted benzophenones such as 4-allylbenzophenone and 4-vinylbenzophenone; alkoxy-substituted benzophenones such as 2-methoxybenzophenone and 4,4′-dimethoxybenzophenone; hydroxy-substituted benzophenones such as 4,4′-dihydroxybenzophenone, 2,4′-dihydroxybenzophenone, and 3,3′-dimethyl-dihydroxybenzophenone; alkyl keto-substituted benzophenones such as 4-acetobenzophenone; alkylthio-substituted benzophenones or alkenylthio-substituted benzophenones such as 4,4′-divinylthiobenzophenone and 4-methylthiobenzophenone; arylthio-substituted benzophenones such as [4-(methylphenylthio)phenyl]-phenylmethane; and ester-substituted benzophenones such as 4,4′-diacetoxybenzophenone, and 4,4′-dimethacryloyloxy benzophenone. One type of these benzophenone-based photopolymerization initiators may be used alone or two or more types may be used in combination.

The benzophenone-based photopolymerization initiator (C) may be used in combination with other photopolymerization initiators to promote curing as long as it does not interfere with the absorption wavelength of the benzophenone-based photopolymerization initiator. In the case where the absorption wavelengths overlap, adhesion to the cycloolefin resin may be lowered.

Examples of the other photopolymerization initiators include benzoin compounds such as benzoin, benzoin methyl ether, benzoin ethyl ether, benzoin propyl ether, and benzoin isobutyl ether; acetophenone compounds such as acetophenone, 2,2-diethoxy-2-phenylacetophenone, 2,2-diethoxy-2-phenylacetophenone, 1,1-dichloroacetophenone, 2-hydroxy-2-methyl-phenylpropan-1-one, diethoxyacetophenone, 1-hydroxycyclohexylphenyl ketone, and 2-methyl-1-[4-(methylthio)phenyl]-2-morpholinopropan-1-one; oxime esters such as 1-[4-(phenylthio)phenyl]-1,2-octanedion-2-(O-benzoyl oxime); anthraquinones such as 2-ethylanthraquinone, 2-tert-butylanthraquinone, 2-chloroanthraquinone and 2-amylanthraquinone; thioxanthones such as 2,4-diethylthioxanthone, 2-isopropylthioxanthone and 2-chlorothioxanthone; ketals such as acetophenone dimethyl ketal and benzyl dimethyl ketal; and phosphine oxides such as 2,4,6-trimethylbenzoyl diphenylphosphine oxide, and bis(2,4,6-trimethylbenzoyl)-phenylphosphine oxide. Furthermore, the photopolymerization initiators may be used in combination with photoinitiation aids including tertiary amines such as triethanolamine and methyldiethanolamine, and benzoic acid derivatives such as N, N-dimethylaminobenzoic acid ethyl ester and N, N-dimethylaminobenzoic acid isoamyl ester.

It is preferable that the film thickness of the cured coating layer (II) of the active energy ray-curable composition be within the range of 0.5 to 20 μm. The film thickness is within the range of preferably 1 to 10 μm, more preferably 3 to 7 μm. With a too small thickness, the desired pencil hardness and steel wool resistance are not obtained. With a too large thickness, the supply of light to the depths of the cured coating layer (II) is hindered during curing, so that crosslinking at the interface between the cured coating layer (II) and the cycloolefin resin substrate (I) proceeds insufficiently, so that adhesion may be lowered.

The active energy ray-curable composition used in the present invention may further contain various additives on an as needed basis, and may be diluted with a solvent as desired. Examples of the usable additives include an ultraviolet absorber, a light stabilizer, an antioxidant, a rheology control agent, a surface conditioner (silicon-based surface conditioner, acrylic-based surface conditioner, fluorine-based surface conditioner, vinyl-based surface conditioner, etc.), a surfactant, resin particles, a lubricant, a defoaming agent, a release agent, a silane coupling agents an antistatic agent, an antifogging agent, and a colorants.

As the UV absorber, conventionally known organic UV absorbers and inorganic UV absorbers may be used, and examples thereof include a benzotriazole-based absorber, a triazine-based absorber, a salicylic acid derivative-based absorber, a benzophenone-based absorber, and other compounds (hydroxyphenyl triazine-based, oxanilide, cyanoacrylate, etc.). Examples of the inorganic UV absorbers include particulate titanium oxide, particulate zinc oxide and particulate iron oxide. The UV absorber may have a polymerizable unsaturated group. In the case where the UV absorber is contained, the content of the UV absorber is within the range of 0.01 to 10 parts by weight, preferably 0.05 to 5 parts by weight, relative to the total components to form a cured film.

The light stabilizer is not particularly limited and a wide variety of conventionally known light stabilizers can be used. Preferred examples thereof include hindered piperidine compounds. Hindered piperidine compounds are compounds having at least one hindered piperidine group in one molecule. Examples of the hindered piperidine compounds include monomer-type compounds such as bis(1,2,2,6,6-pentamethyl-4-piperidyl)sebacate, bis(2,2,6,6-tetramethyl-4-piperidinyl)sebacate, 4-benzoyloxy-2,2,6,6-tetramethylpiperidine, and bis(1,2,2,6,6-pentamethyl-4-piperidyl){[3,5-bis(1,1-dimethylethyl)-4-hydroxyphenyl]methyl}butylmalonate; oligomer-type compounds such as poly{[6-(1,1,3,3-tetramethylbutyl)imino-1,3,5-triazine-2,4-diyl][(2,2,6,6-tetramethyl-4-piperidyl)imino]hexamethylene[(2,2,6,6-tetramethyl-4-piperidyl)iminol]; and polyester bond-type compounds such as a polyesterification product of 4-hydroxy-2,2,6,6-tetramethyl-1-piperidine ethanol and succinic acid; though not limited thereto. As the light stabilizer, known polymerizable light stabilizers may also be used.

Examples of commercially available light stabilizers include TINUVIN 123, TINUVIN 152 and TINUVIN 292 (trade names, manufactured by BASF), HOSTAVIN 3050, HOSTAVIN 3052 and HOSTAVIN 3058 (trade names, manufactured by Clariant), and Adeka STAB LA-82 (trade name, manufactured by ADEKA Corporation). These may be used alone or in combination of two or more. In the case where a light stabilizer is contained, the content thereof is within the range of 0.01 to 10 parts by weight, preferably 0.05 to 5 parts by weight, relative to the total components to form the cured film.

The method for obtaining the cured coating layer (II) may be performed under any of an oxygen-blocking atmosphere or in an air atmosphere. Since good cured films are obtained from the composition of the present invention even under air atmosphere, curing is preferably performed in an air atmosphere. For example, the cured coating layer (II) may be formed by applying the active energy ray-curable composition of the present invention to a cycloolefin resin substrate, or diluting the active energy ray-curable composition with various organic solvents and then applying the composition, and curing the applied composition. Specific examples of the methods include drooling, roller coating, bar coating, spray coating, air knife coating, spin coating, flow coating, curtain coating and dipping. The coating film thickness is adjusted by the solid content concentration in consideration of the film thickness to be formed after drying and curing with an ultraviolet lamp. In the case of using an organic solvent to adjust the solid content concentration, it is preferable to remove the organic solvent by drying or the like after coating. The drying temperature is set such that the substrate for use is not deformed, and the drying time is preferably 1 hour or less from the viewpoint of productivity.

Specific examples of organic solvents include known organic solvents including aromatic organic solvents such as toluene and xylene, ketone-based organic solvents such as methyl ethyl ketone and methyl isobutyl ketone, ester-based organic solvents such as ethyl acetate, n-propyl acetate, isopropyl acetate and isobutyl acetate, alcohol-based organic solvents methanol, ethanol, n-propanol, isopropanol, and n-butanol, and glycol ether-based organic solvents such as propylene glycol monomethyl ether. In particular, a glycol-based organic solvent is preferably included.

Examples of glycol ether-based organic solvents include ethylene glycol ethers such as ethylene glycol monomethyl ether, ethylene glycol monoethyl ether, ethylene glycol dimethyl ether, ethylene glycol diethyl ether, ethylene glycol n-propyl ether, ethylene glycol monoisopropyl ether, ethylene glycol dipropyl ether, ethylene glycol monobutyl ether, ethylene glycol monoisobutyl ether, ethylene glycol dibutyl ether, ethylene glycol isoamyl ether, ethylene glycol monohexyl ether, ethylene glycol mono-2-ethylhexyl ether, methoxy ethoxyethanol and ethylene glycol monoallyl ether; and propylene glycols such as propylene glycol monomethyl ether, propylene glycol monoethyl ether, propylene glycol monopropyl ether, propylene glycol monobutyl ether, and butoxy propanol. In particular, propylene glycol monomethyl ether is preferred.

The laminate according to the present invention may be produced by a method including the steps of: applying an active energy ray-curable composition onto a cycloolefin resin substrate (I) to form a coating layer of the active energy ray-curable composition; exposing the coating layer of the active energy ray-curable composition to active energy rays to form a cured coating layer (II) of the active energy ray-curable composition; and forming at least one inorganic substance layer (III) on the cured coating layer (II) by dry film deposition.

Here, as described above, the active energy ray-curable composition contains the reactive silicone resin (A), the polyfunctional (meth)acrylic monomer (B), and the benzophenone-based photopolymerization initiator (C), and contains 30 to 90 parts by weight of the component (A), 20 to 80 parts by weight of the component (B), and 0.1 to 10 parts by weight of the component (C) relative to 100 parts by weight in total of the components (A), (B), and (C);
the total number of moles of (meth)acrylic of the polyfunctional (meth)acrylic monomer (B) contained in 100 g of the composition is 0.25 to 0.80;
the reactive silicone resin (A) is obtained through hydrolysis and condensation of an alkoxysilane represented by the following general formula (i) and a compound containing an alkyl silicate represented by the following general formula (ii) or a partial hydrolysate thereof, and
the blending ratio between component (i) represented by the formula (i) and a compound containing component (ii) which is an alkyl silicate represented by formula (ii) or a partial hydrolysate thereof satisfies the range: [Moles of Si derived from compound containing component (ii)/Moles of Si derived from component (i)] of 0.5 to 4.0 relative to a total of 100 moles of Si contained in both components:

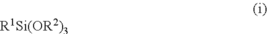

wherein R¹ is an organic functional group having a (meth)acryloyl group, and R² represents a hydrogen atom or an alkyl group having 1 to 5 carbon atoms;

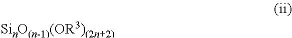

wherein n represents a number of from 1 to 20, and R³ represents a hydrogen atom or an alkyl group having 1 to 5 carbon atoms.

In the active energy ray-curable composition, it is preferable that the polyfunctional (meth)acrylic monomer (B) include, as main component, a polyorganosilsesquioxane represented by the following general formula (iii) and having a cage-type structure in the structural unit,

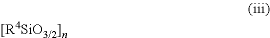

wherein R⁴ is an organic functional group having a (meth)acryloyl group, and n is 8, 10 or 12.

From the active energy ray-curable composition used in the present invention, a cured coating layer (II) excellent in adhesion to both the cycloolefin substrate (I) and the inorganic substance layer (III) can be obtained, and further, a laminate causing no cracking or peeling off in a weather resistance test using a xenon lamp under the specified conditions described above and in the following Examples, excellent in steel wool resistance and pencil hardness, can be formed. For example, the pencil hardness (according to JIS K 5600) is preferably F or higher, more preferably H or higher, and still more preferably 2H or higher.

### EXAMPLES

The present invention is explained in more detail below based on Examples and Comparative Examples, though not limited thereto.

### [Synthesis of A-1]

In a reaction vessel equipped with a stirrer, a dropping funnel and a thermometer, 12.0 g of component (i), which is 3-methacryloxypropyltrimethoxysilane (XIAMETER. OFS-6030 Silane, manufactured by Dow Toray Co., Ltd.),

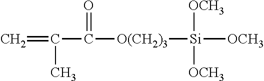

and 16.3 g of component (ii), which is methyl silicate (trade name: Methylsilicate 53A, manufactured by Colcoat Co., Ltd.),

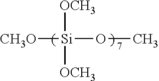

were fed and stirred. In the dropping funnel, 8.7 g of an aqueous solution of 0.05% hydrochloric acid was fed and added to the mixture while stirring at room temperature. After completion of the dropping, the mixture was heated to 60° C. and stirred for 1 hour, then cooled, and 6.6 g of propylene glycol monomethyl ether was added thereto, so that a reactive silicone resin (A-1) having a solid content of 50 wt %, with a ratio of [Moles of Si derived from compounds containing component (ii)/Moles of Si derived from component (i)] of 3.0 relative to 100 moles in total of Si contained in the component (A) was obtained.

### [Synthesis of A-2]

In a reaction vessel equipped with a stirrer, a dropping funnel and a thermometer, 4.5 g of component (i), which is 3-methacryloxypropyltrimethoxysilane (XIAMETER. OFS-6030 Silane, manufactured by Dow Toray Co., Ltd.), and 10.0 g of component (ii), which is methyl silicate (trade name: Methylsilicate 53A, manufactured by Colcoat Co., Ltd.), were fed and stirred. In the dropping funnel, 3.9 g of an aqueous solution of 0.05% hydrochloric acid was fed and added to the mixture while stirring at room temperature. After completion of the dropping, the mixture was heated to 60° C. and stirred for 1 hour, then cooled, and 4.8 g of propylene glycol monomethyl ether was added thereto, so that a reactive silicone resin (A-2) having a solid content of 50 wt %, with a ratio of [Moles of Si derived from compounds containing component (ii)/Moles of Si derived from component (i)] of 1.0 relative to 100 moles in total of Si contained in the component (A) was obtained.

### [Synthesis of A-3]

In a reaction vessel equipped with a stirrer, a dropping funnel and a thermometer, 3.8 g of component (i), which is 3-methacryloxypropyltrimethoxysilane (XIAMETER. OFS-6030 Silane, manufactured by Dow Toray Co., Ltd.), and 12.0 g of methyl silicate (trade name: Methylsilicate 53A, manufactured by Colcoat Co., Ltd.), were fed and stirred. In the dropping funnel, 3.3 g of an aqueous solution of 0.05% hydrochloric acid was fed and added to the mixture while stirring at room temperature. After completion of the dropping, the mixture was heated to 60° C. and stirred for 1 hour, then cooled, and 5.5 g of propylene glycol monomethyl ether was added thereto, so that a reactive silicone resin (A-3) having a solid content of 50 wt %, with a ratio of [Moles of Si derived from compounds containing component (ii)/Moles of Si derived from component (i)] of 0.3 relative to 100 moles in total of Si contained in the component (A) was obtained.

### [Synthesis of A-4]

In a reaction vessel equipped with a stirrer, a dropping funnel and a thermometer, 12.0 g of component (i), which is 3-methacryloxypropyltrimethoxysilane (XIAMETER. OFS-6030 Silane, manufactured by Dow Toray Co., Ltd.), was fed and stirred. In the dropping funnel, 2.7 g of an aqueous solution of 0.05% hydrochloric acid was fed and added while stirring at room temperature. No component (ii) was used. After completion of the dropping, the mixture was heated to 60° C. and stirred for 1 hour, then cooled, and 5.4 g of propylene glycol monomethyl ether was added thereto, so that a reactive silicone resin (A-4) having a solid content of 50 wt %, with no moles of Si derived from compounds containing component (ii), was obtained.

### [Synthesis of B-1]

A reaction vessel equipped with a stirrer, a dropping funnel and a thermometer was charged with 40 ml of 2-propanol (IPA) as solvent and 5% tetramethylammonium hydroxide aqueous solution (TMAH aqueous solution) as basic catalyst. The dropping funnel was charged with 15 ml of IPA and 12.69 g of 3-methacryloxypropyl trimethoxysilane (MTMS) (manufactured by Dow Toray Co., Ltd., XIAMETER, OFS-6030 Silane). While stirring the reaction vessel, the IPA solution of MTMS was added dropwise at room temperature over 30 minutes. After completion of the dropwise addition of MTMS, the mixture was stirred for 2 hours without heating. After stirring for 2 hours, the solvent was removed under reduced pressure and the solute was dissolved into 50 ml of toluene. The reaction solution was washed with saturated saline to be neutralized, and then dehydrated with anhydrous magnesium sulfate. The anhydrous magnesium sulfate was filtered off and 25.8 g of a hydrolysis product (silsesquioxane) was obtained through concentration. The silsesquioxane was a colorless viscous liquid soluble in various organic solvents.

Next, the resulting 20.65 g of silsesquioxane, 82 ml of toluene, and 3.0 g of 10% TMAH aqueous solution were placed in a reaction vessel equipped with a stirrer, a Dean-Stark apparatus, and a condenser, and the mixture was gradually heated so that water was distill off. Further, the mixture was heated to 130° C., and the recondensation reaction was performed at the reflux temperature of toluene. The temperature of the reaction solution at the time was 108° C. After refluxing toluene, stirring was performed for 2 hours, and then the reaction was terminated. The reaction solution was washed with saturated saline to be neutralized, and then dehydrated with anhydrous magnesium sulfate. The anhydrous magnesium sulfate was filtered off, and 18.77 g of a desired cage-type silsesquioxane (mixture) was obtained through concentration. The resulting cage-type silsesquioxane (B-1) was a colorless viscous liquid soluble in various organic solvents.

Through mass spectrometry of the reaction product of recondensation reaction after liquid chromatography separation, molecular ions having ammonium ions attached to the molecular structures (1), (2) and (3) with R representing a methacryloxypropyl group were identified, and the composition ratio T8:T10:T12:others was about 2:4:1:3, so that a silicone resin having a cage structure as main component was identified. Note that T8, T10 and T12 correspond to the structures (1), (2) and (3), with R representing a methacryloxypropyl group, respectively.

The number of moles of acrylic per 100 g of each of T8 (MW=1432), T10 (MW=1790), T12 (Mw=2148) and others obtained after re-condensation reaction is calculated to be the same, i.e. 0.559. Therefore, the number of moles of (meth)acrylic of the component (B) per 100 g of the composition was calculated by multiplying the value described above by the usage ratio in the composition.

### Example 1

An active energy ray-curable composition (II)-1 was obtained by mixing 140 parts by weight of (A-1) as reactive silicone resin (A) component, 30 parts by weight of a mixture (B-2) of dipentaerythritol hexaacrylate (MW=578.57, number of acrylic groups=6) and dipentaerythritol pentaacrylate (Mw=524.52, number of acrylic groups=5) at a weight ratio of 65:35 (manufactured by Kyoeisha Chemical Co., Ltd., trade name: DPHA) as polyfunctional (meth)acrylic monomer (B) component, and 1.5 parts by weight of [4-(methylphenylthio)phenyl]-phenylmethane (C-1) (manufactured by Double Bond Chemical Ind. Co., Ltd., product name BMS) having the chemical structure shown below as benzophenone-based photopolymerization initiator (C).

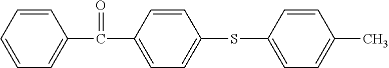 [SMILES: Cc1ccc(Sc2ccc(C(=O)c3ccccc3)cc2)cc1]

The resulting active energy ray-curable composition (II)-1 had a [Moles of Si derived from compound containing component (ii)/Moles of Si derived from component (i)] of 3.0 relative to a total of 100 moles of Si contained in both components, and the number of moles of acrylic of the component (B) per 100 g of the composition was: {[100×(6/578.57)×0.65]+[100×(5/524.52)×0.35]}×(30/101.5)=0.30.

Next, the resulting active energy ray-curable composition (II)-1 was diluted with propylene glycol monomethyl ether to a solid content of 40 parts by weight, and 0.5 parts by weight of acrylic surface conditioner (manufactured by BYK Chemie, trade name BYK3440) were mixed. The mixture was applied to one side of a cycloolefin copolymer resin substrate (thickness: 3 mm, length: 65 mm, width: 35 mm; trade name: APEL5014 manufactured by Mitsui Chemicals, Inc.) in the atmosphere with a spin coater to have a film thickness of 5 μm after drying and dried at 80° C. for 5 minutes, so that a coating layer was formed. Then, the coating layer was cured at an accumulated amount of light of 8400 mJ/cm², so that a cured coating layer (II) of the active energy ray-curable composition was formed on the surface of the cycloolefin copolymer resin substrate. Subsequently, SiO₂ was formed by ion-assisted deposition thereon to have a film thickness of the inorganic substance layer (III) shown in Table 1 of 400 nm. Thus, the laminate of Example 1 was obtained. The inorganic substance layer (III) was silicon dioxide represented by SiOₓ (x:2).

The results are shown in Tables 1 and 2.

In the Tables, [Moles of Si derived from compounds containing component (ii)/Moles of Si derived from component (i)] relative to the total of 100 moles of Si in the component (A) is abbreviated as “Moles of Si derived from component (ii)/Moles of Si derived from component (i)”. Also, the number of moles of (meth)acrylic of component (B) per 100 g of the composition is abbreviated as “moles of (meth)acrylic of component (B)”.

### Examples 2 to 11, and Comparative Examples 1 to 9

The active energy ray-curable compositions (II)-2 to (II)-20 and the laminates each were obtained in the same manner as in Example 1, except that the raw materials and composition ratios shown in Tables 1 and 2 were employed. Other abbreviations in the Tables are as follows.

B-3: a mixture of pentaerythritol tetraacrylate (Mw=352.34, number of acrylic groups=4) and pentaerythritol triacrylate (MW=298.29, number of acrylic groups=3) at a mass ratio of 40:60 (trade name: Light Acrylate PE-3A, manufactured by Kyoeisha Chemical Co., Ltd.)

B-4: dimethylol tricyclodecane diacrylate (Mw=304.39, number of acrylic groups=2, manufactured by Kyoeisha Chemical Co., Ltd., trade name: Light Acrylate DCP-A)

C-2:1-hydroxycyclohexyl phenyl ketone (manufactured by IGM Resins B.V., trade name: Omnirad 184)

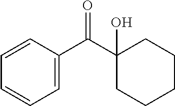 [SMILES: O=C(c1ccccc1)C1(O)CCCCC1]

The laminate test pieces obtained above were subjected to the following evaluation. The evaluation results are shown in Tables 1 and 2.

### [Adhesion]

On the cured film surface of the inorganic substance layer (III) of each laminate test piece, 100 squares of 1 mm×1 mm were made according to JIS K 5600 May 6 (1990), and an adhesive tape was attached to the surface. The adhesive tape was then peeled off rapidly, and the process was repeated three times in total, and the degree of peeling off was evaluated based on the remaining state of the squares according to the following criteria. Regarding the peeling layer, the peeling interface was surveyed by microscopic FT-IR. In the case where a peak derived from the acrylic group was present, peeling between the cured coating layer (II) and the inorganic substance layer (III) was assumed. In the case where a peak derived from the cycloolefin resin substrate (I) was present, peeling between the cycloolefin resin substrate (I) and the cured coating layer (II) was assumed. The adhesion between the cycloolefin resin substrate (I) and the cured coating layer (II), and the adhesion between the cured coating layer (II) and the inorganic substance layer (III) were evaluated, respectively.

In the Tables, the adhesions are written as “(I)/(II)” and “(II)/(III)”, respectively.

Good: The number of remaining squares is 100.

Not good: The number of remaining squares is 90 to 99.

Poor: The number of remaining squares is 0 to 89.

-: Evaluation of “(II)/(III)” is unavailable, due to peeling off at “(I)/(II)”

### [Steel Wool Resistance]

Using #0000 steel wool, the inorganic substance layer (III) surface was abraded 10 times under a load of 0.25 kg/cm² using a reciprocating abrasion tester (Type: 30S manufactured by HEIDON). The occurrence of scratches was visually observed and determined based on the following criteria.
Good: 0 pieces
Not good: 1 piece or more and less than 5 pieces
Poor: 5 pieces or more

### [Appearance]

Occurrence of cracking and peeling off of the laminate were visually observed, and the determination was performed based on the following criteria.

Good: No cracking and no peeling off occur.

Poor: Cracking or peeling off occurs.

### [Pencil Hardness]

According to JIS K 5600, the inorganic substance layer (III) surface of each of the laminate test pieces was scratched with a Mitsubishi pencil Uni at an angle of 45 degrees under a load of 750 g, and the scratch-free hardness was determined visually.

### [Weather Resistance Test]

Using a xenon weather meter tester (X75, manufactured by Suga Test Instruments Co., Ltd.), the inorganic substance layer (III) surface was exposed with light from a xenon lamp at an illuminance of 2.4 W/m² (420 nm) for 150 hours under conditions at a temperature of 55° C. and a relative humidity of 30% Rh, and the appearance, adhesion, steel wool resistance, and pencil hardness after the test were evaluated.

TABLE 1

| | | | Example | Example | Example | Example | Example | Example |
|---|---|---|---|---|---|---|---|---|
| | | | 1 | 2 | 3 | 4 | 5 | 6 |
| Active energy ray-curable composition | | | (II)-1 | (II)-2 | (II)-3 | (II)-4 | (II)-5 | (II)-6 |
| Blending | (A) | A-1 | 70 | 55 | 55 | 55 | 35 | |
| composition | | A-2 | | | | | | 70 |
| | | A-3 | | | | | | |
| | | A-4 | | | | | | |
| | (B) | B-1 | | | | 10 | | |
| | | B-2 | 30 | 45 | | 35 | 65 | 30 |
| | | B-3 | | | 45 | | | |
| | | B-4 | | | | | | |
| | (C) | C-1 | 1.5 | 1.5 | 1.5 | 1.5 | 1.5 | 1.5 |
| | | C-2 | | | | | | |
| Inorganic substance layer (III) | | | SiO_{X} | SiO_{X} | SiO_{X} | SiO_{X} | SiO_{X} | SiO_{X} |
| Moles of Si derived from component (ii)/Moles | | | 3.0 | 3.0 | 3.0 | 3.0 | 3.0 | 1.0 |
| of Si derived from component (i) | | | | | | | | |
| Number of moles of (meth)acrylic of | | | 0.30 | 0.45 | 0.47 | 0.40 | 0.65 | 0.30 |
| component (B) | | | | | | | | |
| Appearance | | Before weather resistance | good | good | good | good | good | good |
| | | test | | | | | | |
| | | After weather resistance test | good | good | good | good | good | good |
| Adhesion | (I)/ | Before weather resistance | good | good | good | good | good | good |
| | (II) | test | | | | | | |
| | | After weather resistance test | good | good | good | good | good | good |
| | (II)/ | Before weather resistance | good | good | good | good | good | good |
| | (III) | test | | | | | | |
| | | After weather resistance test | good | good | good | good | good | good |

| Steel wool | Before weather resistance | good | good | good | good | good | good |
|---|---|---|---|---|---|---|---|
| resistance | test | | | | | | |
| | After weather resistance test | good | good | good | good | good | good |
| Pencil hardness | Before weather resistance | H | H | H | 2H | H | H |
| | test | | | | | | |
| | After weather resistance test | H | H | H | 2H | H | H |

| | | | Example | Example | Example | Example | Example |
|---|---|---|---|---|---|---|---|
| | | | 7 | 8 | 9 | 10 | 11 |
| Active energy ray-curable composition | | | (II)-7 | (II)-8 | (II)-9 | (II)-10 | (II)-11 |
| Blending | (A) | A-1 | | | | | |
| composition | | A-2 | 55 | 55 | 55 | 55 | |
| | | A-3 | | | | | 70 |
| | | A-4 | | | | | |
| | (B) | B-1 | | | 10 | 10 | |
| | | B-2 | 45 | | 35 | 35 | 30 |
| | | B-3 | | 45 | | | |
| | | B-4 | | | | | |
| | (C) | C-1 | 1.5 | 1.5 | 1.5 | 1.5 | 1.5 |
| | | C-2 | | | | 3 | |
| Inorganic substance layer (III) | | | SiO_{X} | SiO_{X} | SiO_{X} | SiO_{X} | SiO_{X} |
| Moles of Si derived from component (ii)/Moles | | | 1.0 | 1.0 | 1.0 | 1.0 | 0.3 |
| of Si derived from component (i) | | | | | | | |
| Number of moles of (meth)acrylic of | | | 0.45 | 0.47 | 0.40 | 0.39 | 0.30 |
| component (B) | | | | | | | |
| Appearance | | Before weather resistance | good | good | good | good | good |
| | | test | | | | | |
| | | After weather resistance test | good | good | good | good | good |
| Adhesion | (I)/ | Before weather resistance | good | good | good | good | good |
| | (II) | test | | | | | |
| | | After weather resistance test | good | good | good | good | good |
| | (II)/ | Before weather resistance | good | good | good | good | good |
| | (III) | test | | | | | |
| | | After weather resistance test | good | good | good | good | not good |

| Steel wool | Before weather resistance | good | good | good | good | good |
|---|---|---|---|---|---|---|
| resistance | test | | | | | |
| | After weather resistance test | good | good | good | good | not good |
| Pencil hardness | Before weather resistance | H | H | 2H | 2H | H |

| | | | | | |
|---|---|---|---|---|---|
| test | | | | | |
| After weather resistance test | H | H | 2H | 2H | H |

TABLE 2

| | | | Comparative | Comparative | Comparative | Comparative | Comparative |
|---|---|---|---|---|---|---|---|
| | | | Example 1 | Example 2 | Example 3 | Example 4 | Example 5 |
| Active energy ray-curable composition | | | (II)-12 | (II)-13 | (II)-14 | (II)-15 | (II)-16 |
| Blending | (A) | A-1 | | 55 | | 70 | |
| composition | | A-2 | | | | | 70 |
| | | A-3 | | | | | |
| | | A-4 | | | 70 | | |
| | (B) | B-1 | 10 | | | | |
| | | B-2 | 90 | 45 | 30 | | |
| | | B-3 | | | | | |
| | | B-4 | | | | 30 | 30 |
| | (C) | C-1 | 1.5 | | 1.5 | 1.5 | 1.5 |
| | | C-2 | | 3 | | | |
| Inorganic substance layer (III) | | | SiO_{X} | SiO_{X} | SiO_{X} | SiO_{X} | SiO_{X} |
| Moles of Si derived from component | | | 0 | 1.0 | 0 | 3.0 | 1.0 |
| (ii)/Moles of Si derived from component (i) | | | | | | | |
| Number of moles of (meth)acrylic of | | | 0.95 | 0.44 | 0.30 | 0.19 | 0.19 |
| component (B) | | | | | | | |
| Appearance | | Before weather resistance | good | good | good | good | good |
| | | test | | | | | |
| | | After weather resistance | good | poor | good | good | good |
| | | test | | | | | |
| Adhesion | (I)/ | Before weather resistance | good | poor | good | not good | not good |
| | (II) | test | | | | | |
| | | After weather resistance | good | poor | good | not good | not good |
| | | test | | | | | |
| | (II)/ | Before weather resistance | good | — | good | good | good |
| | (III) | test | | | | | |
| | | After weather resistance | poor | — | not good | good | good |
| | | test | | | | | |

| Steel wool | Before weather resistance | good | poor | good | not good | not good |
|---|---|---|---|---|---|---|
| resistance | test | | | | | |
| | After weather resistance | poor | poor | not good | poor | poor |
| | test | | | | | |
| Pencil hardness | Before weather resistance | 2H | H | H | H | H |
| | test | | | | | |
| | After weather resistance | <F | <F | H | <F | <F |
| | test | | | | | |

| | | | Comparative | Comparative | Comparative | Comparative |
|---|---|---|---|---|---|---|
| | | | Example 6 | Example 7 | Example 8 | Example 9 |
| Active energy ray-curable composition | | | (II)-17 | (II)-18 | (II)-19 | (II)-20 |
| Blending | (A) | A-1 | 100 | 10 | | |
| composition | | A-2 | | | 100 | 10 |
| | | A-3 | | | | |
| | | A-4 | | | | |
| | (B) | B-1 | | 10 | | 10 |
| | | B-2 | | 80 | | 80 |
| | | B-3 | | | | |
| | | B-4 | | | | |
| | (C) | C-1 | 1.5 | 1.5 | 1.5 | 1.5 |
| | | C-2 | | | | |
| Inorganic substance layer (III) | | | SiO_{X} | SiO_{X} | SiO_{X} | SiO_{X} |
| Moles of Si derived from component | | | 3.0 | 3.0 | 1.0 | 1.0 |
| (ii)/Moles of Si derived from component (i) | | | | | | |
| Number of moles of (meth)acrylic of | | | 0.00 | 0.85 | 0.00 | 0.85 |
| component (B) | | | | | | |
| Appearance | | Before weather resistance | good | good | good | good |
| | | test | | | | |
| | | After weather resistance | poor | poor | poor | poor |
| | | test | | | | |
| Adhesion | (I)/ | Before weather resistance | poor | good | poor | good |
| | (II) | test | | | | |
| | | After weather resistance | poor | good | poor | good |
| | | test | | | | |
| | (II)/ | Before weather resistance | — | good | — | good |
| | (III) | test | | | | |
| | | After weather resistance | — | poor | — | poor |
| | | test | | | | |

| Steel wool | Before weather resistance | poor | good | poor | good |
|---|---|---|---|---|---|
| resistance | test | | | | |
| | After weather resistance | poor | poor | poor | poor |
| | test | | | | |
| Pencil hardness | Before weather resistance | F | H | F | H |

| | | | | |
|---|---|---|---|---|
| test | | | | |
| After weather resistance | <F | <F | <F | <F |
| test | | | | |

1. A laminate, comprising a cycloolefin resin substrate (I) on which a cured coating layer (II) of an active energy ray-curable composition, and an inorganic substance layer (III) are sequentially laminated, wherein
the cured coating layer (II) contains a reactive silicone resin (A), a polyfunctional (meth)acrylic monomer (B), and a benzophenone photopolymerization initiator (C), with a component (A) content of 30 to 90 parts by weight, a component (B) content of 20 to 80 parts by weight, and a component (C) content of 0.1 to 10 parts by weight, relative to 100 parts by weight in total of the components (A), (B), and (C);
a total number of moles of (meth)acrylic of the polyfunctional (meth)acrylic monomer (B) contained in 100 g of the composition is 0.25 to 0.80; and
the reactive silicone resin (A) is obtained through hydrolysis and condensation of an alkoxysilane represented by the following general formula (i) and a compound containing an alkyl silicate represented by the following general formula (ii) or a partial hydrolysate thereof: 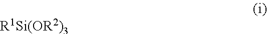
wherein R¹ is an organic functional group having a (meth)acryloyl group, and R² represents a hydrogen atom or an alkyl group having 1 to 5 carbon atoms; 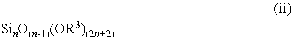
wherein n represents a number of from 1 to 20, and R³ represents a hydrogen atom or an alkyl group having 1 to 5 carbon atoms.

2. The laminate according to claim 1, wherein the laminate in a weather resistance test including exposing a surface of the inorganic substance layer (III) of the laminate to light from a xenon lamp at an illuminance of 2.4 W/m² (420 nm) for 150 hours under conditions at a temperature of 55° C. and a relative humidity of 30% Rh, causes no cracking or no peeling off after the weather resistance test, and no scratches are visually observed after the inorganic substance layer (III) surface is reciprocated 10 times with #0000 steel wool under a load of 0.25 kg/cm².

3. The laminate according to claim 1, wherein a film thickness of the cured coating layer (II) is in the range of 0.5 to 20 μm.

4. The laminate according to claim 1, wherein the cycloolefin resin substrate (I) is not subjected to easy-adhesion processing.

5. An active energy ray-curable composition for forming the cured coating layer (II) of the laminate according to claim 1, comprising:
a reactive silicone resin (A), a polyfunctional (meth)acrylic monomer (B), and a benzophenone photopolymerization initiator (C), with a component (A) content of 30 to 90 parts by weight, a component (B) content of 20 to 80 parts by weight, and component (C) content of 0.1 to 10 parts by weight, relative to 100 parts by weight in total of the components (A), (B), and (C);
wherein a total number of moles of (meth)acrylic of the polyfunctional (meth)acrylic monomer (B) contained in 100 g of the composition is 0.25 to 0.80;
the reactive silicone resin (A) is obtained through hydrolysis and condensation of an alkoxysilane represented by the following general formula (i) and a compound containing an alkyl silicate represented by the following general formula (ii) or a partial hydrolysate thereof, and in the blending ratio between a component (i) represented by the formula (i) and the compound containing a component (ii) as alkyl silicate represented by the formula (ii) or a partial hydrolysate thereof, [Moles of Si derived from compound containing component (ii)/Moles of Si derived from component (i)] satisfies the range of 0.5 to 4.0 relative to 100 moles of Si in total contained in both: 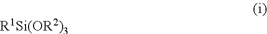
wherein R¹ is an organic functional group having a (meth)acryloyl group, and R² represents a hydrogen atom or an alkyl group having 1 to 5 carbon atoms; 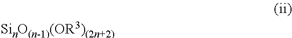
wherein n represents a number of from 1 to 20, and R³ represents a hydrogen atom or an alkyl group having 1 to 5 carbon atoms.

6. The active energy ray-curable composition according to claim 5, wherein the polyfunctional (meth)acrylic monomer (B) includes, as main component, a polyorganosilsesquioxane represented by the following general formula (iii) and having a cage-type structure in the structural unit, 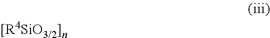
wherein R⁴ is an organic functional group having a (meth)acryloyl group, and n is 8, 10 or 12.

7. A method for producing the laminate according to claim 1, comprising the steps of: applying an active energy ray-curable composition onto a cycloolefin resin substrate (I) to form a coating layer of the active energy ray-curable composition; exposing the coating layer of the active energy ray-curable composition to active energy rays to form a cured coating layer (II) of the active energy ray-curable composition; and forming at least one inorganic substance layer (III) on the cured coating layer (II) by dry film deposition.
